(19) United States
(12) Patent Application Publication
(10) Pub. No.: US 2006/0005107 A1
(43) Pub. Date: Jan. 5, 2006

(54) Error correction in ROM embedded DRAM

(75) Inventors: Scott Derner, Meridian, ID (US); Casey Kurth, Eagle, ID (US); Phillip G. Wald, Boise, ID (US)

Correspondence Address: Leffert Jay & Polglaze, P.A., P.O. Box 581009, Minneapolis, MN, 55402-1009, US

(73) Assignee: Micron Technology, Inc.

(21) Appl. No.: 11/216,280

(22) Filed: Aug. 31, 2005

Related U.S. Application Data
(62) Division of application No. 10/022,010, filed on Dec. 13, 2001.

(51) Int. Cl. G11C 29/00

(52) U.S. Cl. 714/763

(57) ABSTRACT

Error correction through the use of on memory encoded error correction circuitry or parity checking circuitry allow for error correction in a read only memory (ROM) embedded dynamic random access memory (DRAM).

### CROSS-REFERENCE TO RELATED APPLICATION

This is a divisional application of U.S. patent application Ser. No. 10/022,010, titled “ERROR CORRECTION IN ROM EMBEDDED DRAM” filed Dec. 13, 2001 (pending), which application is assigned to the assignee of the present invention and the entire contents of which are incorporated herein by reference.

### FIELD

The present invention relates generally to memory devices, and more specifically to a read only memory (ROM) embedded in a dynamic random access memory (DRAM).

### BACKGROUND

Problems with DRAM and errors have been addressed with redundancy schemes. Similarly, problems with ROM embedded DRAM redundancy have been addressed. However, the redundancy schemes, while reducing the likelihood that an error will scrap a part, still offer limited ability to repair errors.

ROM parts have in the past used error correcting code (ECC) for error correction in ROMs. However, in a ROM embedded DRAM, there are different ROM schemes for generating ROM bits. Those schemes do not lend themselves to the same ECC solutions as traditional ROM bits. For example, traditional ROM cells are made with intersecting rows and columns like standard DRAM, but where the columns and rows intersect, where RAM uses transistors to turn on or off access to a capacitor at each intersection, some ROMs uses a diode to connect the lines if the value is a “1.” If the value is “0,” then the lines are not connected at all. Other ROMs use a transistor to short a specific row and column location to ground of to a supply voltage such as V_{CC} to create the ROM bit.

Traditional DRAM repair includes using redundancy schemes such as row or column replacement, or mapping a defective bit or block of bits to a redundant array in order to effect repairs to the memory. While such schemes do offer some repair, at times a greater degree of certainty is desired.

There is therefore a need in the art for an improved correction of errors in a ROM embedded DRAM.

### SUMMARY

In one embodiment, a ROM embedded DRAM includes a DRAM array having a first portion of ROM cells and a second portion of DRAM cells, wherein the ROM cells are formed by hard shorting DRAM cells within the DRAM array, and correction circuitry fabricated on and integrated with the DRAM.

In another embodiment, a method of fabricating a ROM embedded DRAM includes forming an array of DRAM cells having a first portion of ROM cells and a second portion of DRAM cells, programming a ROM portion of the DRAM cells as ROM bits, and encoding the ROM bits in error correction circuitry.

In yet another embodiment, a method of operating a ROM embedded DRAM includes receiving a row and column address to read data from a ROM section, reading an encoded ROM bit, correcting the read ROM bit if necessary, and presenting the corrected ROM bit as output data.

In still another embodiment, a ROM embedded DRAM includes a DRAM array having a first portion of ROM bits and a second portion of DRAM bits, and an error correction element containing encoded ROM bit data for each ROM bit.

In yet another embodiment, a method of repairing ROM bit errors in a ROM embedded DRAM includes programming a ROM section of a ROM embedded DRAM, encoding ROM data in error correction circuitry, determining whether the ROM bit data is correct, and correcting the ROM bit data if the ROM bit data and the stored data are different.

Other embodiments are described and claimed.

### BRIEF DESCRIPTION OF THE DRAWINGS

FIG. 1 is a block diagram of a ROM embedded DRAM on which embodiments of the present invention are practiced;

FIG. 2 is a block diagram of a ROM embedded DRAM according to one embodiment of the present invention;

FIG. 3 is a flow chart diagram of a method according to one embodiment of the present invention;

FIG. 4 is a flow chart diagram of a method according to another embodiment of the present invention;

FIG. 5 is a block diagram of a ROM embedded DRAM according to another embodiment of the present invention; and

FIG. 6 is a block diagram of a ROM embedded DRAM according to yet another embodiment of the present invention.

### DETAILED DESCRIPTION

In the following detailed description of the embodiments, reference is made to the accompanying drawings which form a part hereof, and in which is shown by way of illustration specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention.

The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors, and the term insulator is defined to include any material that is less electrically conductive than the materials referred to as conductors. The following detailed description is, therefore, not to be taken in a limiting sense, and the scope of the present invention is defined only by the appended claims, along with the full scope of equivalents to which such claims are entitled.

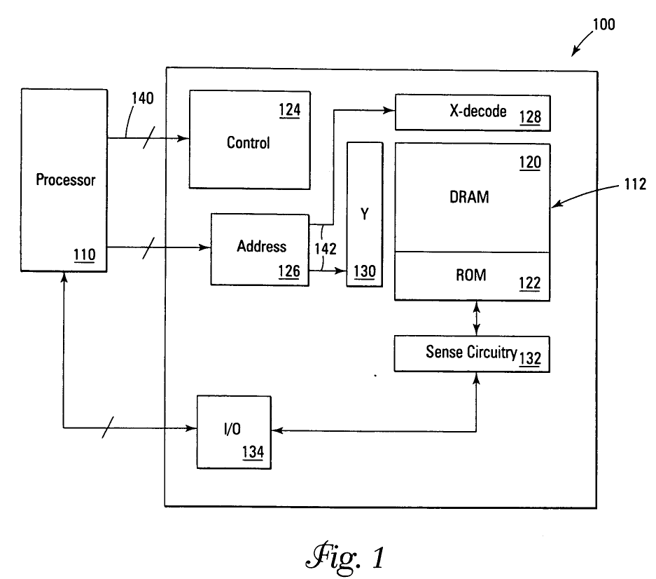

Referring to FIG. 1, a simplified block diagram of a ROM embedded DRAM 100 of the present invention is described. The memory device can be coupled to a processor 110 for bi-directional data communication. The memory includes an array of memory cells 112. The array includes a dynamic (DRAM) portion 120 and a read only (ROM) portion 122. The ROM array is “embedded” in the dynamic memory and may include some dynamic cells. Control circuitry 124 is provided to manage data storage and retrieval from the array in response to control signals 140 from the processor. Address circuitry 126, X-decoder 128 and Y-decoder 130 analyze address signals 142 and storage access locations of the array. Sense circuitry 132 is used to read data from the array and couple output data to I/O circuitry 134. The I/O circuitry operates in a bi-directional manner to receive data from processor 110 and pass this data to array 112. It is noted that the sense circuitry may not be used in some embodiments to store the input data.

Dynamic memories are well known, and those skilled in the art will appreciate that the above-described ROM embedded DRAM has been simplified to provide a basic understanding of DRAM technology and is not intended to describe all of the features of a DRAM. The present invention uses the basic architecture and fabrication techniques of a DRAM and provides an embedded ROM array for non-volatile storage of data. This data can be used to store boot-type data for a system, a non-volatile look-up table, or other data that does not require a dedicated ROM memory device. Embedding ROM storage in a DRAM is most economically beneficial if the DRAM is not substantially altered during fabrication or operation. That is, small fabrication changes allow the embedded memory to be fabricated using known techniques. Further, it is desired to maintain operation of the memory in a manner that is externally transparent. As such, an external processor, or system, does not need special protocol to interface with the embedded memory.

One technique for physically programming ROM embedded cells is described in U.S. Pat. No. 6,134,137 issued Oct. 17, 2000 entitled “ROM-Embedded-DRAM”, incorporated herein by reference. U.S. Pat. No. 6,134,137 teaches that slight modifications in fabrication masks allow DRAM cells to be hard programmed to V_{CC} or V_{SS} by shorting the cell to word lines. The memory reads the ROM cells in a manner that is identical to reading the DRAM cells. As described below, the present invention provides an improved ROM embedded DRAM.

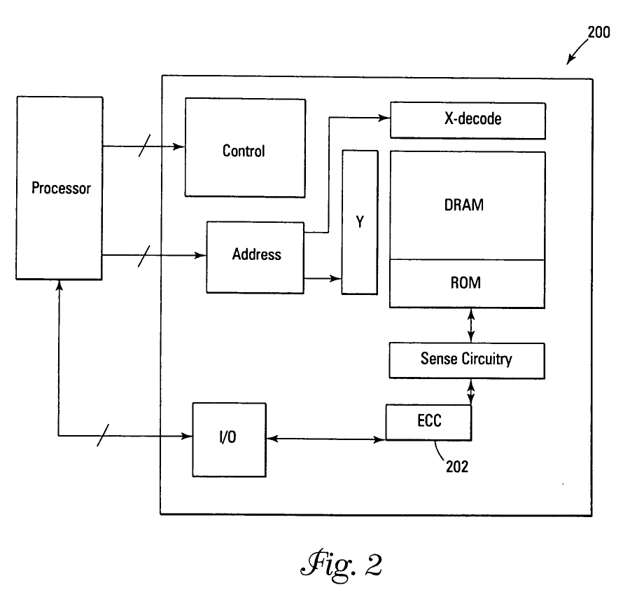

One embodiment of an ECC enabled ROM embedded DRAM 200 is shown in FIG. 2. ROM embedded DRAM 200 comprises a ROM embedded DRAM such as memory 100 described above, and further includes ECC circuitry 202 integrated with the ROM embedded DRAM. The ROM embedded DRAM 200 is designed to include on-memory error correction circuitry logic to free a processor such as processor 110 or other dedicated ECC circuitry/hardware from decoding ECC encoded ROM data. The ROM embedded DRAM 200 has built in ECC, such that the error correction and decoding hardware for the error correction is fabricated right along with the memory itself. When the ROM bits are programmed, they are also encoded with ECC code. The hardware for decoding the ECC information is built right into the DRAM array itself.

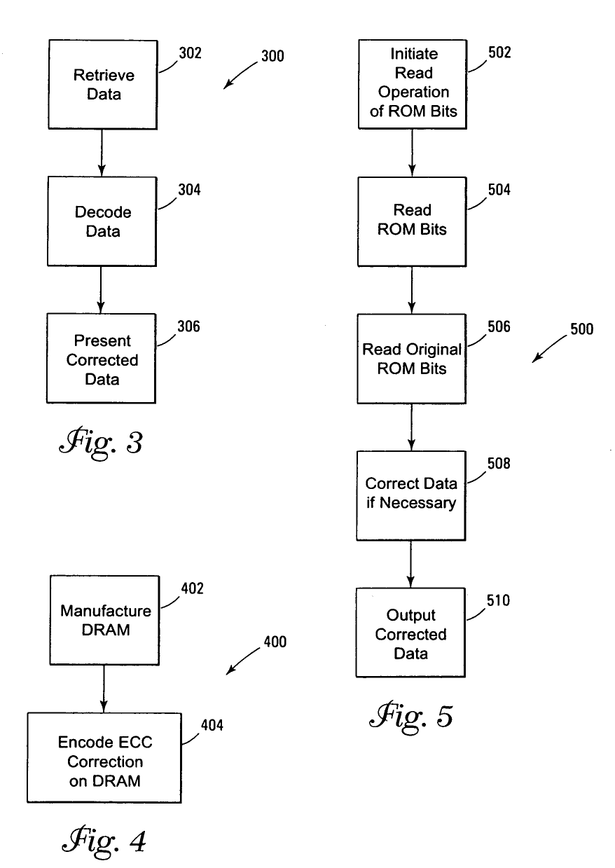

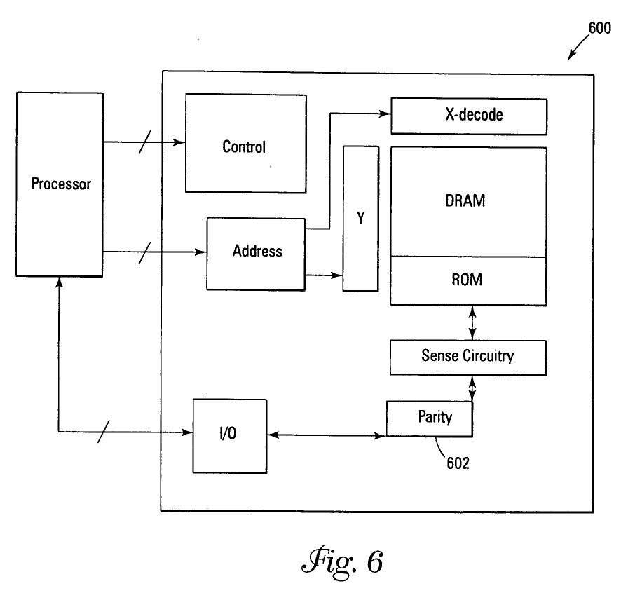

When a read operation is commenced, the desired data is retrieved from the array. The process 300 shown in FIG. 3 for retrieving, however, comprises retrieving the data which is ECC encoded in block 302, decoding the data in block 304, and presenting corrected data out from the memory in block 306. The data out from the memory has been ECC corrected if necessary, and is presented to the end user seamlessly. There is a small speed tradeoff between uncorrected data reads and ECC corrected data reads, but the small speed reduction is balanced by the correction of errors. Typically, ROM reads do not need to be performed with speed as the key factor, and therefore, a slight speed reduction does not negatively affect overall ROM operation.

Error correcting code uses multiple bits to allow decoding software or hardware to determine not only that an error is present in a read of information, but also to correct the error if it is not catastrophic. For example, if individual bit errors occur in a ROM embedded DRAM ROM portion, the ECC hardware encoding and decoding built into the memory detects and corrects the errors when a read operation takes place.

A method embodiment 400 for making a ROM embedded DRAM with ECC comprises manufacturing a DRAM array in block 402, and encoding ECC correction during the manufacturing process in block 404. The hardware for ECC decoding is provided in the memory. The inclusion of ECC decoding logic removes any need for any external ECC decoding hardware or software.

A method of operating a ROM embedded DRAM with error correction is shown in flow chart diagram in FIG. 5. Method 500 comprises initiating a read operation of the ROM bits of the ROM embedded DRAM in block 502, and reading the ROM bits in block 504. Reading the ROM bits comprises a standard read operation, but the operation is performed through the ECC logic, so that the original ROM data is read in block 506, the data is corrected if necessary in block 508, and the corrected data is output in block 510.

The ECC logic used for the DRAM array that forms the ROM section of the ROM embedded DRAM is amenable to several forms of encoding as is known in the art. Such schemes for implementing error correction are not discussed further herein. While certain error correction techniques have been specifically discussed herein, it should be understood that other error correcting techniques are also amenable to use with the various embodiment of the present invention without departing from its scope. Error correction techniques include by way of example only and not by way of limitation, parity, Hamming code, modified Hamming code, Gray code, polynomial checking, cyclical redundancy checking, and the like.

It should be understood that any one of a number of methods for creating ROM bits from a DRAM array to form a ROM embedded DRAM are amenable to the embodiments of the present invention without departing from its scope. ROM bits are hard programmed in a ROM embedded DRAM by any number of programming techniques, including by way of example only and not by way of limitation, hard programming by eliminating cell dielectric to short cell plates to a program voltage, or by fabricating an electrical plug between the cell plates and shorted to a program voltage, programming using an anti-fuse programming technique, or by providing a high leakage path (not full short) such as through an active area to the substrate.

In the embodiment wherein ECC decode logic for the ROM bits is included on the ROM embedded DRAM removes the need for a processor or other hardware or software to have to decode and fix defective bits. In other words, the ECC is hard coded into the programmed ROM bits, and is read by the customer. Since the ROM portion of the array does not need to have the same read access time as DRAM portions of the array, the small access time speed lost due to read time for extra bits dedicated to ECC logic is acceptable.

In another embodiment 600, parity checking for determination and correction of ROM bit errors is used. ROM embedded DRAM 600 comprises a memory such as memory 100 described above, having also formed thereon and integrated with the memory parity checking elements 602.

Traditional parity checking reads the number of “1” bits in a byte, and sets a parity bit to a “1” or a “0” depending upon the type of parity. Even parity sets the parity bit to “1” if the number of “1” bits is odd. Odd parity sets the parity bit to “1” if the number of “1” bits is even. The parity bit is generated on a write, and checked on a read. If it matches each time, data is assumed to be okay. If not, the data is discarded.

Traditional parity checking cannot correct errors, but can alert the user to random errors in processing of the ROM cells. However, if parity checking is performed for each ROM bit of the ROM section of a ROM embedded DRAM, for example, then single bit errors are all that will occur, since single bits are being examined.

In the embodiment 600, parity checking is used with a ROM section of a ROM embedded DRAM. Parity checking is capable of determining a single error. Since each memory cell comprises a single bit, detection of a single bit error is sufficient to not only detect but to correct errors in the ROM section of the ROM embedded DRAM. In this embodiment, parity checking is built into the DRAM array so that each and every bit has an associated parity bit therewith. Then, parity operates as normal. Upon detection of an error through the parity bit, the polarity of the bit is changed.

In this configuration, parity checking, while potentially costly in terms of extra components, allows correction of even single bit errors. In a single bit situation, parity checking reveals an error that can then be corrected by inverting the received data bit. In an alternative embodiment, a redundancy scheme such as that described in co-pending application entitled ROM REDUNDANCY IN ROM EMBEDDED DRAM, assigned to the assignee of the present application, is employed in combination with the parity checking. The processes by which ECC logic is fabricated with DRAM is shown for example in U.S. Pat. Nos. 5,134,616 and 5,307,356.

A parity checked ROM embedded DRAM operates as follows. A request is received for the data stored in a particular ROM bit of the ROM embedded DRAM. The ROM bits have been encoded with party checking as described above. The particular bit which has been requested is decoded and checked for errors with parity checking. If the bit is in error, it is corrected before it is sent as data out.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method of fabricating a ROM embedded DRAM, comprising:
forming an array of DRAM cells having a first portion of ROM cells and a second portion of DRAM cells;
programming a ROM portion of the DRAM cells as ROM bits; and
encoding the ROM bits in error correction circuitry.

2. The method of claim 1, wherein encoding comprises:
encoding with ECC circuitry.

3. The method of claim 1, wherein encoding comprises:
encoding with parity checking circuitry.

4. The method of claim 1, wherein encoding comprises:
hard programming an error correction portion of the ROM bits of the ROM embedded DRAM.

5. The method of claim 4, wherein hard programming comprises:
eliminating a cell dielectric to short cell plates to a program voltage.

6. The method of claim 4, wherein hard programming comprises:
fabricating an electrical plug between cell plates and shorted to a program voltage.

7. The method of claim 4, wherein hard programming comprises:
programming using an anti-fuse programming technique,

8. The method of claim 4, wherein hard programming comprises:
providing a high leakage path through an active area to a substrate.

9. The method of claim 1, wherein the correction circuitry is fabricated at the time of manufacture of the ROM embedded DRAM.

10. The method of claim 1, wherein the correction circuitry is hard coded.

11. The method of claim 1, wherein the error correction circuitry is chosen from a group consisting of:
parity, Hamming code, modified Hamming code, Gray code, polynomial checking, and cyclical redundancy checking.

12. A method of fabricating a ROM embedded DRAM, comprising:
forming an array of DRAM cells having a first portion of ROM cells and a second portion of DRAM cells;
programming a ROM portion of the DRAM cells as ROM bits; and
providing error correction for the ROM portion of the DRAM cells.

13. The method of claim 12, wherein providing error correction further comprises:
fabricating error correction at the time of manufacture of the ROM embedded DRAM.

14. The method of claim 12, wherein programming the ROM portion further comprises:
programming a first section of the ROM portion with ROM cells dedicated to memory operations and a second section of the ROM portion with ROM cells dedicated to error correction.

15. The method of claim 14, wherein programming the ROM provides parity checking.

16. The method of claim 15, wherein providing parity checking further comprises:
dedicating one error correction ROM cell to each memory operation ROM cell.

17. The method of claim 1, wherein providing error correction further comprises:
hard programming an error correction portion of the ROM bits of the ROM embedded DRAM.

18. The method of claim 17, wherein hard programming comprises:
eliminating a cell dielectric to short cell plates to a program voltage.

19. The method of claim 17, wherein hard programming comprises:
fabricating an electrical plug between cell plates and shorted to a program voltage.

20. The method of claim 17, wherein hard programming comprises:
programming using an anti-fuse programming technique,

21. The method of claim 17, wherein hard programming comprises:
providing a high leakage path through an active area to a substrate.

22. The method of claim 12, wherein the error correction circuitry is chosen from a group consisting of:
parity, Hamming code, modified Hamming code, Gray code, polynomial checking, and cyclical redundancy checking.
